(19) United States
(12) Patent Application Publication
(10) Pub. No.: US 2006/0244050 A1
(43) Pub. Date: Nov. 2, 2006

(54) Semiconductor device and method of fabricating the same

(75) Inventor: Jinsuke Sudou, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/410,932

(22) Filed: Apr. 26, 2006

(30) Foreign Application Priority Data
Apr. 28, 2005 (JP) 2005-131531

(51) Int. Cl. H01L 29/792

(52) U.S. Cl. 257/324

(57) ABSTRACT

A semiconductor device 100 is configured as having a semiconductor substrate 102 having a first-conductivity-type semiconductor region 104 formed in its surficial portion; an anode 146 of a Schottky barrier diode formed on the first-conductivity-type semiconductor region 104; a second-conductivity-type guard ring 114 formed along the periphery of the anode 146 in the surficial portion of the first-conductivity-type semiconductor region; an isolation insulating film 108 formed along the periphery of, and being spaced from, the guard ring 114 in the surficial portion of the first-conductivity-type semiconductor region 104, so as to isolate the anode 146 from the other regions; and an anode-forming mask 110a covering the surface of the semiconductor substrate in a portion fallen between the anode 146 and the isolation insulating film 108, and being in contact with the end portion of the anode 146.

This application is based on Japanese patent application No. 2005-131531 the content of which is incorporated hereinto by reference.

### BACKGROUND

1. Technical Field

The present invention relates to a semiconductor device and a method of fabricating the same.

2. Related Art

FIG. 11 is a sectional view showing a configuration of a semiconductor device described in Japanese Laid-Open Patent Publication No. H01-246873. The semiconductor device has a Schottky electrode 32 forming a Schottky diode on a first-conductivity-type (N-type) semiconductor region 31, and a guard ring 33 composed of a second-conductivity-type (P-type) impurity region around the Schottky diode. The semiconductor device herein further contains a doped semiconductor layer 34 provided in connection with the guard ring, and the doped semiconductor layer 34 is formed in contact with the Schottky electrode 32 of the Schottky barrier diode, so as to exclude any sidewall placed therebetween. This reportedly makes it possible to improve the voltage resistance of the Schottky barrier diode, and to avoid unnecessary increase in the area due to the sidewall, or to avoid unstable variation in the distance between the guard ring and the Schottky electrode 32. Reference numeral 44 denotes a thick oxide film, and 52 denotes an insulating layer.

Schottky barrier diode generally has an anode and a cathode formed on a semiconductor substrate as being spaced from each other. Wider distance between the electrodes worsens the forward current efficiency. It is preferable to narrow as possible the distance, also in view of downsizing the semiconductor device. However, the semiconductor device described in Japanese Laid-Open Patent Publication No. H01-246873, having the doped semiconductor layer 34 formed aside the Schottky electrode 32, inevitably widens the distance between the Schottky electrode 32 (anode) and the opposing electrode (cathode). This worsens the forward current efficiency, and inhibits downsizing of the semiconductor device.

FIG. 12 is a partially-enlarged sectional view schematically showing a configuration of the semiconductor device described in Japanese Laid-Open Patent Publication No. H01-246873.

A semiconductor region 31, having an insulating material such as device isolation insulating film 44 formed therein, generally has a defect layer formed therein, at the interface with the device isolation insulating film 44. When the Schottky electrode 32 is applied with reverse voltage, a depletion layer is formed at the junction between the P-type guard ring 33 and the N-type semiconductor region 31. Growth of the depletion layer formed at the junction between the P-type guard ring 33 and the N-type semiconductor region 31 to as far as to overlap the defect layer will result in increase in reverse leakage current through the defect layer, and this makes it difficult to realize a high-voltage Schottky barrier diode.

In the semiconductor device described in Japanese Laid-Open Patent Publication No. H01-246873, the doped semiconductor layer 34 is formed in contact with the Schottky electrode 32. Application of a reverse voltage to the Schottky electrode 32 therefore sets also the doped semiconductor layer 34 at the same potential. The doped semiconductor layer 34 is formed over the entire region of the semiconductor region 31 between the isolation insulating film 44 and the guard ring 33, while placing a thin insulating film 48 in between. This allows the depletion layer, formed at the interface between the P-type guard ring 33 and the N-type semiconductor region 31, to reach as far as the defect layer due to field plate effect of the doped semiconductor layer 34, and consequently increases the reverse current leakage through the defect layer.

As has been described in the above, the semiconductor device disclosed in Japanese Laid-Open Patent Publication No. H01-246873 is still on the way in terms of realizing a high-voltage Schottky barrier diode, improving the current efficiency of Schottky barrier diode, and in downsizing the semiconductor device.

### SUMMARY OF THE INVENTION

According to the present invention, there is provided a semiconductor device, including: a semiconductor substrate having a first-conductivity-type region formed in its surficial portion; a metal electrode of a Schottky barrier diode formed on the first-conductivity-type region; a second-conductivity-type region formed along the periphery of the metal electrode in the surficial portion of the first-conductivity-type region; an isolation insulating film formed along the periphery of, and being spaced from, the second-conductivity-type region in the surficial portion of the first-conductivity-type region, so as to isolate the metal electrode from the other regions; and an insulating film covering the surface of the semiconductor substrate in a portion fallen between the metal electrode and the isolation insulating film, and being in contact with the end portion of the metal electrode.

The second-conductivity-type region herein may be a guard ring region. In the present invention, the insulating film limits the position of the end portion of the metal electrode. This makes it possible to form the metal electrode at a desired position relative to the second-conductivity-type region and to the isolation insulating film. The metal electrode can be formed as being spaced from the isolation insulating film. This makes it possible to ensure a desirable Schottky contact between the metal electrode and the semiconductor substrate, without allowing the metal electrode to overlap the defect layer formed at the interface between the first-conductivity-type region and the isolation insulating film. It is also made possible to suppress defect-induced leakage current. In addition, the metal electrode can be formed so as to locate the end portion thereof on the second-conductivity-type region which serves as the guard ring. This makes it possible to further improve the Schottky contact between the metal electrode and the semiconductor substrate, and to effectively suppress the defect-induced leakage current. It is still also made possible to moderate concentration of electric field to the end portion of the metal electrode.

The insulating film and the metal electrode are provided in contact with each other, without placing any other constituents in between, raising an advantage of downsizing the semiconductor device. It is also made possible to improve current efficiency between the metal electrode and the opposing electrode, because the distance between these electrodes can be shortened.

In the present invention, the second-conductivity-type region and the isolation insulating film are kept distant from each other. In other words, the present invention can configure the semiconductor device so that a PN junction plane between the second-conductivity-type region and the first-conductivity-type region, differing in the conductivity type from each other, can be kept distant from the isolation insulating film. The distance between the second-conductivity-type region and the isolation insulating film can be determined, so that the depletion layer in a portion of the first-conductivity-type region between the second-conductivity-type region and the isolation insulating film, as being extended from the interface with the second-conductivity-type region, does not overlap the defect layer produced in the first-conductivity-type region along the interface thereof with the isolation insulating film. This makes it possible to suppress the reverse leakage current and therefore to realize a high-voltage Schottky barrier diode.

According to the present invention, there is also provided method of fabricating a semiconductor device containing a Schottky barrier diode, including: forming, in a first-conductivity-type region formed in the surficial portion of a semiconductor substrate, and around a metal electrode forming region of a Schottky barrier diode, an isolation insulating film isolating the metal electrode forming region from the other regions as being spaced from the metal electrode forming region; forming a second-conductivity-type region along the periphery of the metal electrode forming region, and as being spaced from the isolation insulating film; forming an insulating film covering the surface of the semiconductor substrate in a portion fallen between the metal electrode forming region and the isolation insulating film; and forming a metal electrode in the metal electrode forming region, using the insulating film as a mask.

In this process, either of the step of forming the second-conductivity-type region and the step of forming the insulating film may precede the other. In the method of fabricating a semiconductor device, the metal electrode can be formed at a desired position using the insulating film as a mask. This makes it possible to form the metal electrode at a desired position relative to the second-conductivity-type region and the isolation insulating film.

The present invention can therefore suppress the reverse leakage current in the Schottky barrier diode, to thereby realize a high-voltage Schottky barrier diode.

### BRIEF DESCRIPTION OF THE DRAWINGS

The above and other objects, advantages and features of the present invention will be more apparent from the following description taken in conjunction with the accompanying drawings, in which:

FIG. 1 is a sectional view showing a configuration of a semiconductor device according to an embodiment of the present invention;

FIG. 2 is an enlarged sectional view showing a region between the guard ring and the isolation insulating film of the semiconductor device shown in FIG. 1;

FIG. 3 is a horizontal sectional view showing a configuration of the semiconductor device shown in FIG. 1;

FIGS. 4A to 4C, 5A to 5C, 6A to 6C and 7 are sectional views showing process steps of fabricating the semiconductor device according to the embodiment of the present invention;

FIGS. 8A to 8C, 9A and 9B are sectional views showing process steps of fabricating the semiconductor device according to another embodiment of the present invention;

FIG. 10 is a sectional view showing another exemplary configuration of the semiconductor device shown in FIG. 1;

FIG. 11 is a sectional view showing a configuration of a conventional semiconductor device; and

FIG. 12 is a partially enlarged sectional view schematically showing a configuration of the semiconductor device shown in FIG. 11.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Paragraphs below will explain embodiments of the present invention, referring to the attached drawings. It is to be noted that, in all of the drawings, any similar constituents will be given with the same reference numerals, allowing omission of repetitive explanations for simplicity.

The embodiments below will deal with exemplary cases where the first conductivity type is N-type, and the second conductivity type is P-type.

### First Embodiment

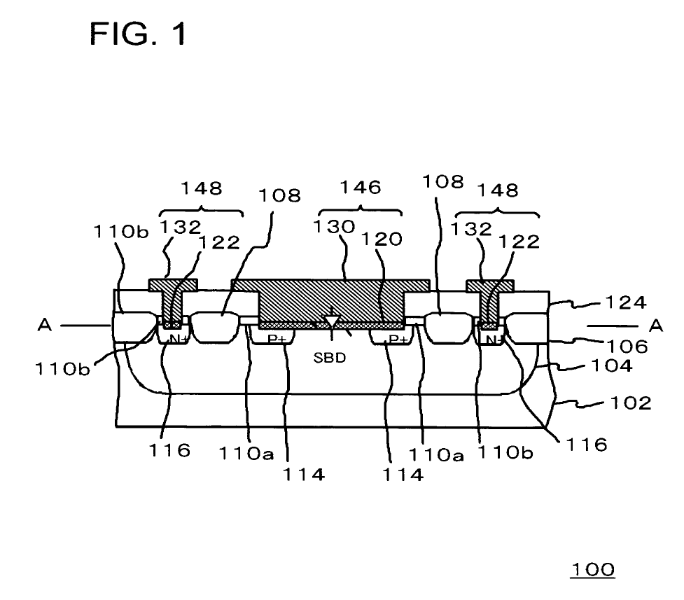

FIG. 1 is a sectional view showing a configuration of a semiconductor device of this embodiment.

A semiconductor device 100 has a semiconductor substrate 102 having a first-conductivity-type semiconductor region 104 (first-conductivity-type region) formed in the surficial portion thereof; an anode 146 (metal electrode) of a Schottky barrier diode formed on the first-conductivity-type semiconductor region 104; a second-conductivity-type guard ring 114 formed along the periphery of the anode 146 in the surficial portion of the first-conductivity-type semiconductor region 104, and; an isolation insulating film 108 formed along the periphery of, and being spaced from, the guard ring 114 in the surficial portion of the first-conductivity-type semiconductor region 104, so as to isolate the anode 146 from the other regions; and an anode-forming mask 110a covering the surface of the semiconductor substrate in a portion fallen between the anode 146 and the isolation insulating film 108, and being in contact with the end portion of the anode 146. The semiconductor device 100 further includes an isolation insulating film 106, a cathode-forming mask 110b, contact region 116, a second insulating film 124, and a cathode 148. In this embodiment, the first-conductivity-type semiconductor region 104 and the contact region 116 are composed of N-type impurity diffused region. The guard ring 114 has a second conductivity type, reverse to the first conductivity type. The guard ring 114 in this embodiment is configured by a P-type impurity diffused region.

The anode-forming mask 110a and the cathode-forming mask 110b are configured by an insulating film. The anode 146 includes a first silicide electrode 120 and a first metal electrode 130. The cathode 148 includes a second silicide electrode 122 and a second metal electrode 132. The semiconductor substrate 102 in this embodiment is a silicon substrate.

In this embodiment, the guard ring 114 is disposed as being spaced from the isolation insulating film 108. The first silicide electrode 120 of the anode 146 is disposed as being more largely spaced from the isolation insulating film 108. The first silicide electrode 120 is disposed so as to locate the end portion thereof on the guard ring 114.

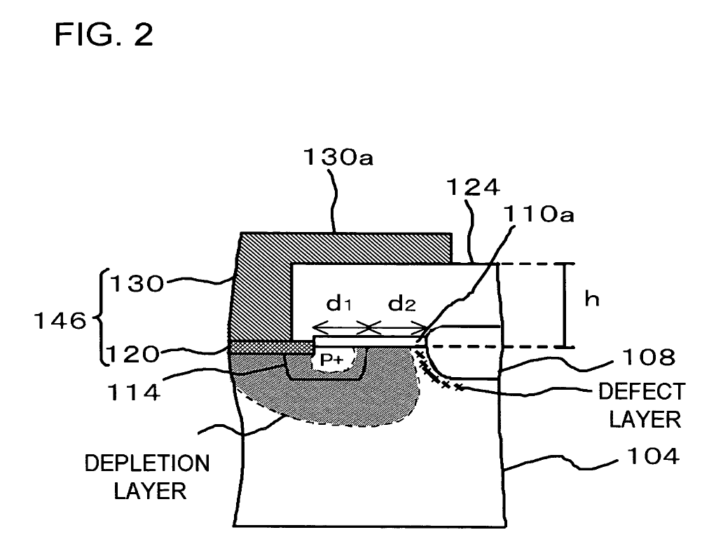

FIG. 2 is an enlarged sectional view showing a region between the guard ring 114 and the isolation insulating film 108 of the semiconductor device 100 shown in FIG. 1.

When a reverse voltage is applied between the anode 146 and the cathode 148 (not shown in FIG. 2), a depletion layer generates at the junction between the guard ring 114 and the first-conductivity-type semiconductor region 104. The guard ring 114 is formed as being spaced from the isolation insulating film 108 to a degree allowing the depletion layer, formed at the junction between the guard ring 114 and the first-conductivity-type semiconductor region 104, never to overlap the interface between the defect layer formed at the interface between first-conductivity-type semiconductor region 104 and the isolation insulating film 108. Distance d₂ between the outer end portion of the guard ring 114 and the end portion of the isolation insulating film 108 differs depending on value of voltage applied between the anode 146 and the cathode 148, impurity concentrations of the first-conductivity-type semiconductor region 104 and the guard ring 114, and other conditions.

A maximum width lₙ of the depletion layer in the first-conductivity-type semiconductor region 104 is expressed by the equation below, using impurity concentration of the first-conductivity-type semiconductor region 104 given as N_{D}, impurity concentration of the guard ring 114 as NA, charge of electron as q, dielectric constant of semiconductor as ε, dielectric constant of vacuum as ε₀, diffusion potential between the first-conductivity-type semiconductor region 104 and the guard ring 114 as φ_{D}, and a maximum value of voltage applied between the anode 146 and the cathode 148 as V (Furukawa, “Handoutai Debaisu (Semiconductor Device)”, 10th edition revised, Corona Publishing Co., Ltd., Feb. 20, 1991, p. 36):

$$ln = \sqrt{\frac{2 ɛ {ɛ}_{0}}{{qN}_{D}} ( {Φ}_{D} - V )} \cdot \sqrt{\frac{{N}_{A}}{{N}_{A} + {N}_{D}}}$$

It is therefore understood that distance d₂ can be determined as larger than the total of lₙ, and the width of the defect layer at the interface between the first-conductivity-type semiconductor region 104 and the isolation insulating film 108. This makes it possible to allow the depletion layer formed at the junction between the guard ring 114 and the first-conductivity-type semiconductor region 104 never to reach the defect layer. With this structure, reverse current leakage through the defect layer can be reduced, and therefore a high-voltage Schottky barrier diode can be realized.

The maximum value V of voltage applied between the anode 146 and the cathode 14 varies typically depending on purposes of use of the semiconductor device 100, and may typically be set to 15 to 50 V. Also impurity concentration ND of the first-conductivity-type semiconductor region 104, and impurity concentration N_{A} of the guard ring 114 vary typically depending on purposes of use of the semiconductor device 100, and may typically be set to N_{D}=1E15 to 1E17 atoms·cm⁻³, and to N_{A}=5E16 to 5E20 atoms·cm⁻³.

Distance d₂ between the outer end portion of the guard ring 114 and the end portion of the isolation insulating film 108 can specifically be adjusted to d₂=0.5 μm or more. This makes it possible to reduce the reverse current leakage because the depletion layer in the first-conductivity-type semiconductor region 104 will no more overlap the defect layer at the interface with the isolation insulating film 108, and thereby to realize a high-voltage Schottky barrier diode.

The upper limit of d₂ can be set to d₂=2.5 μm or less, for example. This makes it possible to downsize the semiconductor device 100, without unnecessarily elongate the distance between the guard ring 114 and the isolation insulating film 108. It is also made possible to keep a good level of the forward current efficiency of Schottky barrier diode.

There is no special limitation on distance d₁ between the end portion of the first silicide electrode 120 and the outer end portion of the guard ring 114, so far as the first silicide electrode 120 is kept fallen on the guard ring 114, and the distance may typically be set to 0.1 μm to 1.0 μm. This realizes a configuration in which the end portion of the first silicide electrode 120 can be disposed always on the guard ring 114.

As shown in FIG. 2, the first metal electrode 130 of the anode 146 in this embodiment has an extended portion 130a provided as being extended on the second insulating film 124. The second insulating film 124 in this embodiment is formed to a thickness enough for preventing first-conductivity-type semiconductor region 104, located between the guard ring 114 and the isolation insulating film 108, from being affected by the field plate effect ascribable to the extended portion 130a, even under voltage applied between the anode 146 and the cathode 148.

A preferable value of the total thickness (height) h of the second insulating film 124 and the anode-forming mask 110a varies depending typically on dielectric constants of the insulating films composing these constituents, and may typically be set to 200 nm or more, and more preferably to 500 nm or more. This makes it possible to prevent the first-conductivity-type semiconductor region 104 from being affected by the field plate effect ascribable to the extended portion 130a of the first metal electrode 130, and thereby to suppress spreading of the depletion layer in the first-conductivity-type semiconductor region 104 under voltage application.

In particular in a region above the junction plane between the first-conductivity-type semiconductor region 104 and the isolation insulating film 108, it is made possible to exclude the metal electrode over a range of h. This makes it possible to prevent the depletion layer in the first-conductivity-type semiconductor region 104 from spreading closer to the isolation insulating film 108.

Although not shown in the drawing, the semiconductor device 100 may include a multi-layered interconnection structure formed on the second insulating film 124. The extended portion 130a of the first metal electrode 130 may be formed in the same layer with the first metal layer in the multi-layered interconnection structure. In other words, it is made possible in this embodiment to exclude any component electrically affective to the first-conductivity-type semiconductor region 104 from a region above the junction plane between the first-conductivity-type semiconductor region 104 and the isolation insulating film 108, over a range from the surface of the semiconductor substrate 102 up to the level of the layer same as the first metal layer in the multi-layered interconnection structure.

The upper limit of the thickness of the second insulating film 124 is not specially limited, and may typically be set to 1000 nm or less. This facilitates formation-by-filling of the metal electrodes such as first metal electrode 130 and the second metal electrode 132.

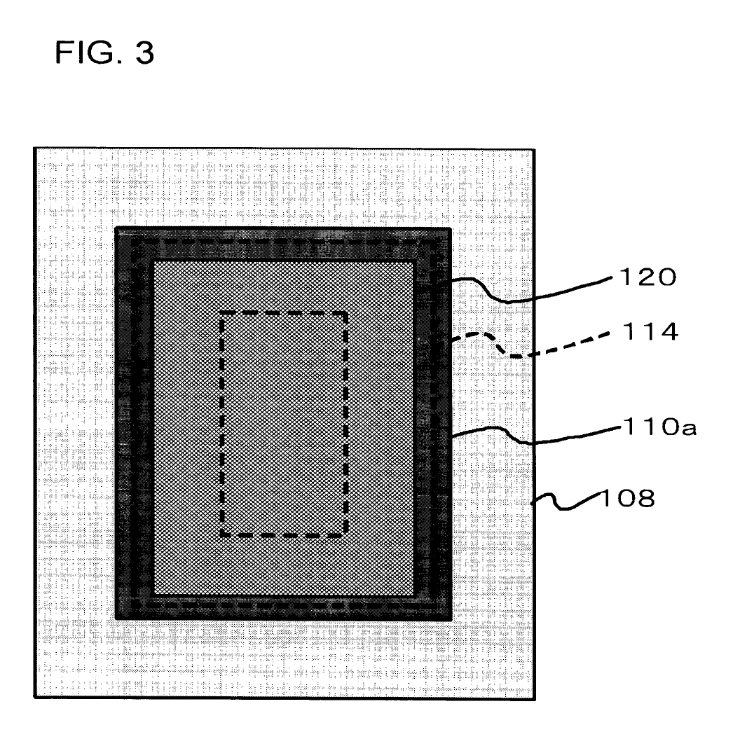

FIG. 3 is a horizontal sectional view showing a configuration of the semiconductor device 100 shown in FIG. 1, taken along line A-A.

The first silicide electrode 120 in this embodiment is formed according to a rectangular pattern in a plan view. The guard ring 114 is formed along the periphery of the first silicide electrode 120. The isolation insulating film 108 is provided at around the guard ring 114, as being spaced from the guard ring 114. A region between the guard ring 114 and the isolation insulating film 108 is covered with the anode-forming mask 110a. The first silicide electrode 120 is provided in contact with, rather than allowing the end portion thereof to overlap, the anode-forming mask 110a. In other words, the end portion of the first silicide electrode 120 and the end portion of the anode-forming mask 110a are in contact with each other.

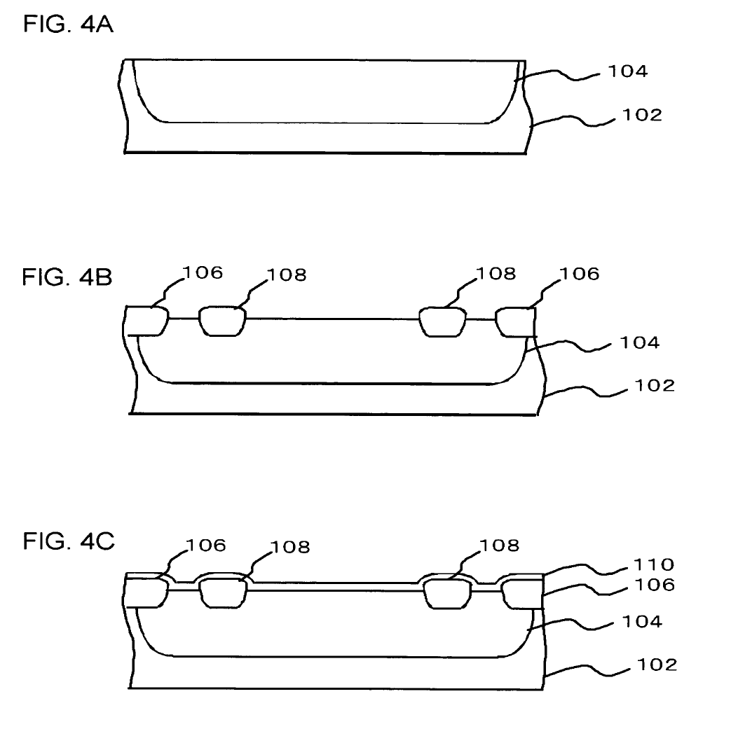

FIGS. 4A to 4C, 5A to 5C, 6A to 6C and 7 show process steps of fabricating the semiconductor device 100 of this embodiment.

First, the first-conductivity-type semiconductor region 104 as an N-type impurity diffused region is formed on the semiconductor substrate 102 (FIG. 4A). The surface concentration of an N-type impurity in the first-conductivity-type semiconductor region 104 can be adjusted to 1E15 atoms·cm⁻³ to 1E17 atoms·cm⁻³. This ensures a good Schottky contact.

Next, the isolation insulating film 106 and the isolation insulating film 108 are formed in the first-conductivity-type semiconductor region 104 by a general self-aligning isolation technique (FIG. 4B). The isolation insulating film 106 and the isolation insulating film 108 can be formed by the STI (shallow trench isolation) process or the LOCOS (local oxidation of silicon) process. The isolation insulating film 106 and the isolation insulating film 108 herein may typically be composed of a silicon oxide film. In the later processes, the anode 146 is formed between two isolation insulating films 108 shown in this sectional view. Between the isolation insulating film 108 and the isolation insulating film 106, the cathode 148 is formed. The distance between two isolation insulating films 108 can be designed based on size of the first silicide electrode 120 to be formed later, distance d₁ between the end portion of the first silicide electrode 120 and the outer end portion of the guard ring 114, and distance d₂ between the outer end portion of the guard ring 114 and the end portion of the isolation insulating film 108. In the process steps of fabricating the semiconductor device 100, the individual constituents can be designed taking process variations into account.

Next, a first insulating film 110 is formed on at least a portion of the semiconductor substrate 102 having the first-conductivity-type semiconductor region 104 exposed therein (FIG. 4C). The first insulating film 110 is configured in the later process so as to function as a mask for forming the silicide film selectively in a predetermined portion on the first-conductivity-type semiconductor region 104. The first insulating film 110 is therefore configured by a material capable of interfering growth of the silicide film in the region having the first insulating film 110 formed therein. The first insulating film 110 is also formed to a thickness capable of interfering the growth of the silicide film in the region having the first insulating film 110 formed therein. The first insulating film 110 may typically be composed of a silicon oxide film. The thickness of the first insulating film 110 can be adjusted to 20 nm or more, for example. The first insulating film 110 can be formed by the thermal oxidation process or the CVD (chemical vapor deposition) process. According to such configuration, it is made possible to interfere the silicidation in the region, having the first insulating film 110 formed therein, on the surface of the semiconductor substrate 102.

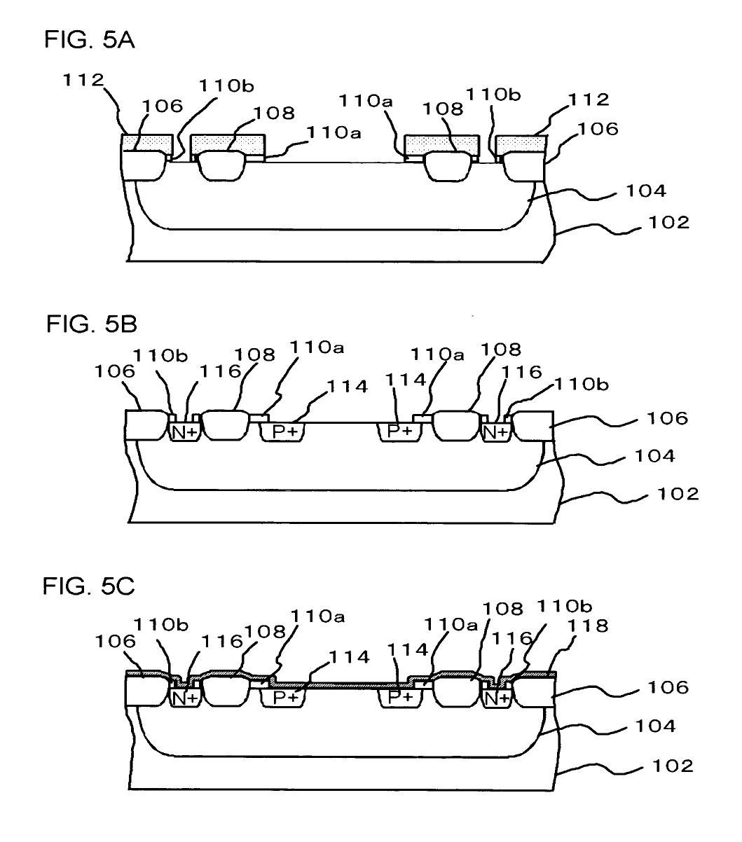

The first insulating film 110 is selectively removed by a general lithographic technique, and to thereby form the anode-forming mask 110a and the cathode-forming mask 110b (FIG. 5A). More specifically, the process begins with a photoresist process forming a resist layer 112 having a predetermined pattern, as a mask through which the first insulating film 110 is selectively removed.

The first insulating film 110 is then selectively removed using the resist layer 112 by an etching technique such as wet etching or dry etching, to thereby allow the first-conductivity-type semiconductor region 104 to expose in the region where the first silicide electrode 120 is formed later. At the same time, the first-conductivity-type semiconductor region 104 is allowed to expose also in the region where the second silicide electrode 122 is formed later. The anode-forming mask 110a and the cathode-forming mask 110b are thus formed. Because the anode-forming mask 110a functions as a mask through which the first silicide electrode 120 is formed on the semiconductor substrate 102, it is formed to a width of d=d₁+d₂.

The guard ring 114 and the contact region 116 are then formed respectively by a photoresist process and ion implantation (FIG. 5B). The guard ring 114, which is a P⁺ layer, and the contact region 116, which is an N⁺ layer, are formed respectively according to the processes described below. First, a resist layer having an opening in an ion implantation region formed therein is formed on the semiconductor substrate 102 by a photoresist process. Ion implantation is then carried out through the resist layer as a mask.

The guard ring 114 herein is formed so as to adjust the distance between the outer end portion thereof and the end portion of the isolation insulating film 108 to d₂ described in the above. The guard ring 114 is formed also so as to allow the end portion of the anode-forming mask 110a to fall thereon. In other words, as shown in FIG. 2, the guard ring 114 is formed so as to overlap the anode-forming mask 110a by a length equivalent to distance of d₁.

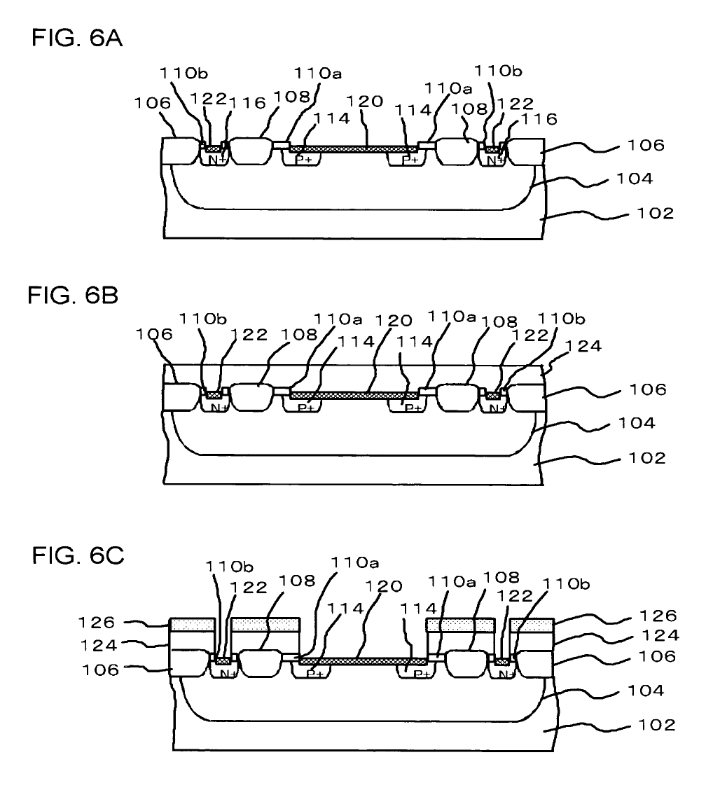

Next, a metal film 118 is formed over the entire surface of the semiconductor substrate 102, typically by sputtering or CVD (FIG. 5C). In this embodiment, the metal film 118 can be composed of Ti, Co, Ni or the like. Annealing is then carried out so as to proceed silicidation between the semiconductor substrate, which is a silicon substrate, and the metal film 118. Annealing temperature herein is appropriately set depending on species of the metal film 118, and is typically selected in the range from 500° C. to 800° C. or around. The anode-forming mask 110a and the cathode-forming mask 110b in this embodiment are formed so as to function as a mask for silicidation as described in the above, so that the first silicide electrode 120 and the second silicide electrode 122 are formed in a self-aligned manner in the region where the first-conductivity-type semiconductor region 104 comes into contact with the metal film 118 (FIG. 6A).

Next, the second insulating film 124 is formed over the entire surface of the semiconductor substrate 102 (FIG. 6B). As described in the above, the second insulating film 124 is formed to a thickness sufficient for reducing electrical influence on the first-conductivity-type semiconductor region 104 ascribable to the extended portion 130a of the first metal electrode 130 formed later. The second insulating film 124 may be formed typically to as thick as 200 nm or more in total with the thickness of the anode-forming mask 110a. More preferably, the second insulating film 124 may be formed to as thick as 500 nm or more in total with the thickness of the anode-forming mask 110a. This makes it possible to suppress spreading of the depletion layer in the first-conductivity-type semiconductor region 104 under voltage application.

Next, the second insulating film 124 is selectively removed by a general lithographic technique (FIG. 6C). More specifically, a resist layer 126 having a predetermined pattern is formed by a photoresist process, as a mask through which the second insulating film 124 is selectively removed. The second insulating film 124 herein may have a pattern same with those of the anode-forming mask 110a and the cathode-forming mask 110b formed previously in the process step shown in FIG. 5A. In other words, the resist layer 126 is formed according to the same pattern with the resist layer 112 shown in FIG. 5A. The second insulating film 124 is then selectively removed through the resist layer 126 as a mask, by an etching technique such as wet etching or dry etching.

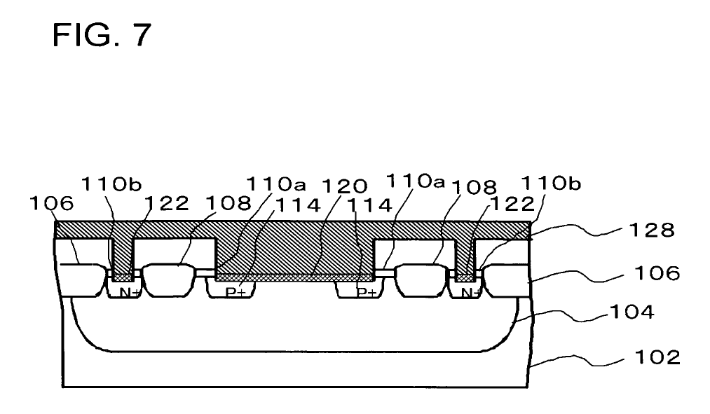

A metal film 128 is then formed by sputtering or CVD over the entire surface of the semiconductor substrate 102 (FIG. 7). The metal film 128 can be configured by a material capable of ensuring a good ohmic contact with the silicide films such as the first silicide electrode 120 and the second silicide electrode 122. Applicable examples of such material include TiN, W, Al, Cu and the like.

The metal film 128 is then selectively removed by a photoresist process and dry etching process to thereby form the first metal electrode 130 and the second metal electrode 132. The semiconductor device 100 configured as shown in FIG. 1 is thus obtained.

The semiconductor device 100 of this embodiment makes it possible to allow the depletion layer extending between the guard ring 114 and the isolation insulating film 108 never to overlap the defect layer under voltage application to the Schottky barrier diode. It is therefore made possible to suppress the reverse current leakage, and consequently to realize a high-voltage Schottky barrier diode.

On the surface of the semiconductor substrate 102, the position of the anode 146 is limited by the anode-forming mask 110a. This makes it possible to locate the anode 146 at a desired position relative to the guard ring 114 and the isolation insulating film 108. It is also made possible to downsize the semiconductor device 100. It is still also made possible to minimize as possible the distance between the anode 146 and the cathode 148, while keeping a distance necessary for suppressing the above-described reverse current leakage, and thereby to improve the forward current efficiency.

### Second Embodiment

This embodiment differs from the first embodiment in the configuration of the anode 146 and the cathode 148.

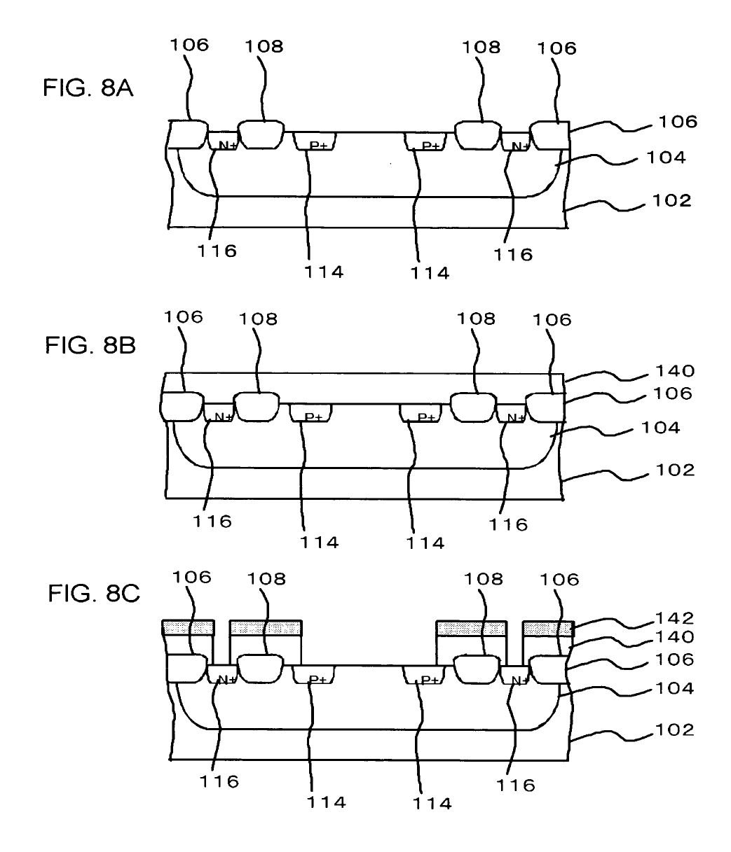

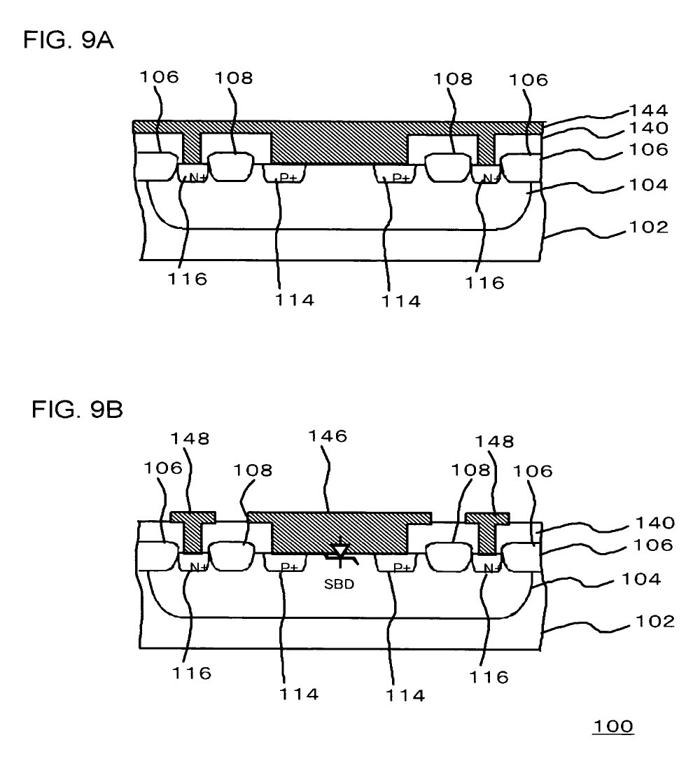

FIGS. 8A to 9B are sectional views showing process steps of fabricating a semiconductor device of this embodiment.

First, a structure configured as shown in FIG. 4B is formed according to the similar procedures as described in the first embodiment referring to FIGS. 4A and 4B. Next, the guard ring 114, which is a P⁺ layer, and the contact region 116, which is an N⁺ layer, are respectively formed by a photoresist process and ion implantation (FIG. 8A). The guard ring 114 herein is formed so as to ensure the above-described distance d₂ between the outer end portion thereof and the end potion of the isolation insulating film 108, as described in the first embodiment. The guard ring 114 is formed also so as to allow the end portion of the anode-forming mask 110a to fall thereon. In other words, as shown in FIG. 2, the guard ring 114 is formed so as to overlap the anode-forming mask 110a by a length equivalent to distance of d₁.

Next, a third insulating film 140 is formed over the entire surface of the semiconductor substrate 102 typically by the thermal oxidation process or the CVD process (FIG. 6B). The thickness of the third insulating film 140 can be set equivalent to the total thickness of the anode-forming mask 110a and the second insulating film 124 in the first embodiment. The thickness of the third insulating film 140 can be adjusted typically to 200 nm or more, and more preferably to 500 nm or more. The thickness of the third insulating film 140 can be set, for example, to 1000 nm or less.

Next, the third insulating film 140 is selectively removed by a general lithographic technique (FIG. 8C). More specifically, the process begins with a photoresist process forming a resist layer 142 having a predetermined pattern, as a mask through which the third insulating film 140 is selectively removed. The resist layer 142 herein is formed according to the same pattern with the resist layer 112 shown in the first embodiment. The third insulating film 140 is then selectively removed through the resist layer 142 as a mask, by an etching technique such as wet etching or dry etching.

A metal film 144 is then formed by sputtering or CVD over the entire surface of the semiconductor substrate 102 (FIG. 9A). The metal film 144 can be configured by using TiN, W, Al, Cu or the like.

Next, the metal film 144 is selectively removed by a photoresist process and dry etching, to thereby form the anode 146 and the cathode 148 (FIG. 9B).

Also this embodiment is successful in obtaining effects similar to those in the first embodiment.

The foregoing paragraphs have explained the present invention referring to the specific embodiments. The embodiments in the above are merely of exemplary purposes, so that those skilled in the art can readily understand that there are various possible modifications for combinations of the individual constituents and the individual process steps, and that also these modifications are within a scope of the present invention.

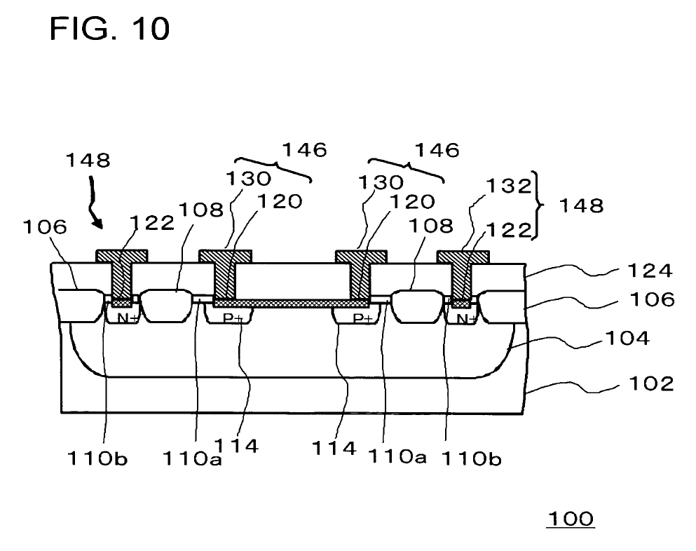

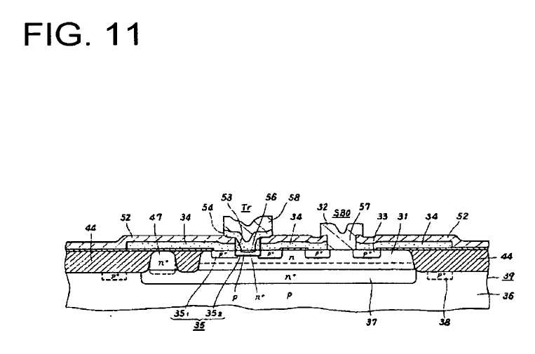

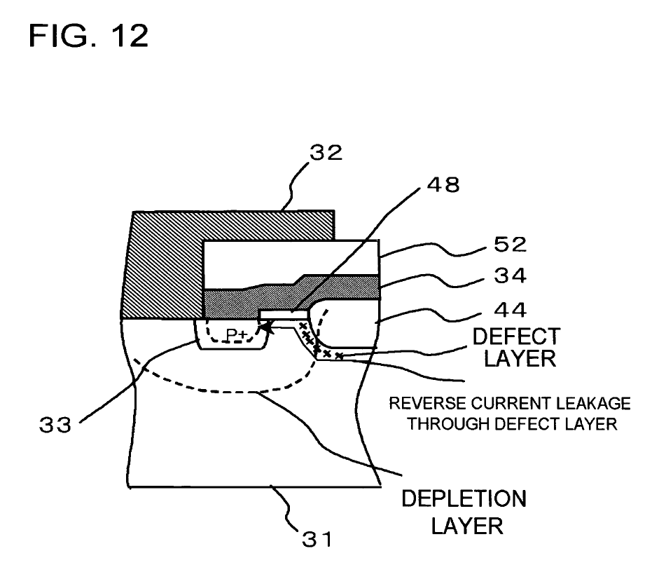

FIG. 10 is a sectional view showing another exemplary configuration of the semiconductor device 100 explained in the first embodiment. The first embodiment showed a configuration in which the first metal electrode 130 was formed over the entire surface of the first silicide electrode 120 of the anode 146, whereas it is also allowable to form the first metal electrode 130 only above the position where the guard ring 114 was formed.

The above embodiments have described the exemplary cases where the first conductivity type was defined as N-type and the second conductivity type as P-type, whereas it is also allowable to define the first conductivity type as P-type and the second conductivity type as N-type. In this case, the anode 146 (first silicide electrode 120 and the first metal electrode 130) in the first embodiment, and the anode 146 in the second embodiment can be configured using, for example, Mg, Mg—Al alloy and so forth.

It is apparent that the present invention is not limited to the above embodiments, and may be modified and changed without departing from the scope and spirit of the invention.

What is claimed is:

1. A semiconductor device, comprising:
a semiconductor substrate having a first-conductivity-type region formed in its surficial portion;
a metal electrode of a Schottky barrier diode formed on said first-conductivity-type region;
a second-conductivity-type region formed along the periphery of said metal electrode in the surficial portion of said first-conductivity-type region;
an isolation insulating film formed along the periphery of, and being spaced from, said second-conductivity-type region in the surficial portion of said first-conductivity-type region, so as to isolate said metal electrode from the other regions; and
an insulating film covering the surface of said semiconductor substrate in a portion fallen between said metal electrode and said isolation insulating film, and being in contact with the end portion of said metal electrode.

2. The semiconductor device as claimed in claim 1, wherein said insulating film has a thickness of 200 nm or more above a portion fallen between said second-conductivity-type region and said isolation insulating film of the surficial portion of said first-conductivity-type region.

3. The semiconductor device as claimed in claim 1, wherein said metal electrode contains a silicide film formed in contact with said semiconductor substrate and provided in contact with said insulating film.

4. The semiconductor device as claimed in claim 2, wherein said metal electrode contains a silicide film formed in contact with said semiconductor substrate and provided in contact with said insulating film.

5. The semiconductor device as claimed in claim 1, further comprising an opposing electrode of said Schottky barrier diode, formed on said first-conductivity-type region; and
said isolation insulating film is disposed between said metal electrode and said opposing electrode, so as to allow voltage to be applied between said metal electrode and said opposing electrode.

6. The semiconductor device as claimed in claim 2, further comprising an opposing electrode of said Schottky barrier diode, formed on said first-conductivity-type region; and
said isolation insulating film is disposed between said metal electrode and said opposing electrode, so as to allow voltage to be applied between said metal electrode and said opposing electrode.

7. A method of fabricating a semiconductor device containing a Schottky barrier diode, comprising:
forming, in a first-conductivity-type region formed in the surficial portion of a semiconductor substrate, and around a metal electrode forming region of a Schottky barrier diode, an isolation insulating film isolating said metal electrode forming region from the other regions as being spaced from said metal electrode forming region;
forming a second-conductivity-type region along the periphery of said metal electrode forming region, and as being spaced from said isolation insulating film;
forming an insulating film covering the surface of said semiconductor substrate in a portion fallen between said metal electrode forming region and said isolation insulating film; and
forming a metal electrode in said metal electrode forming region, using said insulating film as a mask.

8. The method of fabricating a semiconductor device as claimed in claim 7, wherein
said semiconductor substrate is a silicon substrate; and
said forming a metal electrode further comprises:
forming a metal material layer on the entire surface of said semiconductor substrate; and
allowing the surface of said metal electrode forming region of said semiconductor substrate to react with said metal material to produce silicide.
